(19) United States
(12) Patent Application Publication
(10) Pub. No.: US 2012/0150454 A1
(43) Pub. Date: Jun. 14, 2012

(54) APPARATUS AND METHOD FOR MANAGING ENERGY RESOURCES

(75) Inventors: Jihyun LEE, Daejeon (KR); Ji Yeon Son, Daejeon (KR); Young Sung Son, Daejeon (KR); Hark Jin Lee, Daejeon (KR); Jeu Young Kim, Daejeon (KR); Jun Hee Park, Daejeon (KR); Kyeong Deok Moon, Daejeon (KR)

(73) Assignee: Electronics and Telecommunications Research Institute, Daejeon (KR)

(21) Appl. No.: 13/305,984

(22) Filed: Nov. 29, 2011

(30) Foreign Application Priority Data
Dec. 9, 2010 (KR) 10-2010-0125850

(51) Int. Cl. G06F 19/00; G01F 1/00; G01R 21/00

(52) U.S. Cl. 702/45; 702/62

(57) ABSTRACT

An apparatus for managing energy resources includes: a collection unit for collecting energy consumptions and resource information of a plurality of energy consumption devices; an integrated resource relation map management unit for generating and managing an integrated resource relation map which indicates correlations between energy resources one another consumed by the energy consumption devices by using the energy consumptions and the resource information; and an energy management unit for generating energy-saving measures based on the integrated resource relation map.

### CROSS-REFERENCE(S) TO RELATED APPLICATION(S)

The present invention claims priority of Korean Patent Application No. 10-2010-0125850, filed on Dec. 9, 2010, which is incorporated herein by reference.

### FIELD OF THE INVENTION

The present invention relates to a management method for saving energy; and, more particularly, to an apparatus and method for managing energy resources which present energy-saving measures to help a user effectively save energy.

### BACKGROUND OF THE INVENTION

Recently, various methods which allow a user to easily catch the consumption of all kinds of energy resources in a house or in a building thereby helping the user save energy have been introduced. Along with that, there have been proposed methods which attract a user to save energy by exhibiting a usage charge depending on actual energy usage until the present.

Most of such existing energy-saving methods just provide energy consumption amounts, on a monthly basis, consumed by a variety of devices such as electronic equipments, gas equipments and water equipments consuming energy resources in a house or in a building, as monitoring information of energy resources. Thus, a user needs to find a way for saving energy by catching energy usage through the monitoring information. That is, the existing energy-saving methods fail to provide effective energy-saving measures.

Basic energy management methods also collect only monitoring information of each resource to provide the same to a user, and thus have difficulty in managing relations between individual resources and in providing information by various groups such as areas, usage amounts, types and characteristics as well as by resources.

Accordingly, it is required a method which estimates energy usage by a certain period and calculates a corresponding usage charge to show them to a user, and recommends to a user effective energy-saving measures by individual energy resources or by various groups based on the estimated energy usage and the corresponding usage charge.

### SUMMARY OF THE INVENTION

In view of the above, the present invention provides an apparatus and method for managing energy resources, which construct an integrated resource relation map based on information of energy used in a house or a building, calculate actual energy usage and its corresponding usage charge, predict future energy usage and its corresponding usage charge, and present energy-saving measures by groups, thereby helping a user effectively save energy.

Further, the present invention provides an apparatus and method for managing energy resources, which manage relation information between individual energy resources and provide information of each of various groups such as areas, kinds, characteristics of the resources, thereby helping a user more effectively save energy.

In accordance with an aspect of the present invention, there is provided an apparatus for managing energy resources, including:

a collection unit for collecting energy consumptions and resource information of a plurality of energy consumption devices;

an integrated resource relation map management unit for generating and managing an integrated resource relation map which indicates correlations between energy resources one another consumed by the energy consumption devices by using the energy consumptions and the resource information; and

an energy management unit for generating energy-saving measures based on the integrated resource relation map.

In accordance with another aspect of the present invention, there is provided a method for managing energy resources, including:

collecting energy consumptions and resource information of a plurality of energy consumption devices;

generating an integrated resource relation map which indicates correlations between energy resources one another consumed by the energy consumption devices by using the energy consumptions and the resource information; and

generating energy-saving measures based on the integrated resource relation map.

### BRIEF DESCRIPTION OF THE DRAWINGS

The objects and features of the present invention will become apparent from the following description of embodiments, given in conjunction with the accompanying drawings, in which:

FIG. 1 illustrates a detailed block diagram of an apparatus for managing energy resources based on an integrated resource relation map in accordance with an embodiment of the present invention;

FIG. 2 depicts a detailed block diagram of an energy management unit shown in FIG. 1;

FIG. 3 illustrates a detailed block diagram of an integrated resource relation map management unit shown in FIG. 1; and

FIG. 4 is a flowchart showing an operation of the apparatus for managing energy resources based on the integrated resource relation map in accordance with the embodiment of the present invention.

### DETAILED DESCRIPTION OF THE EMBODIMENTS

Hereinafter, embodiments of the present invention will be described with reference to the accompanying drawings which form a part hereof.

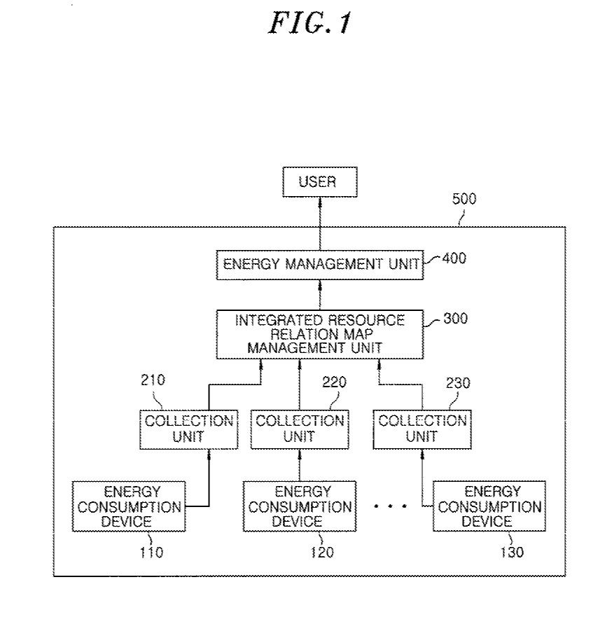

FIG. 1 illustrates a detailed block diagram of an apparatus for managing energy resources based on an integrated resource relation map in accordance with an embodiment of the present invention.

Referring to FIG. 1, the apparatus 500 for managing energy resources includes energy consumption devices 110, 120 and 130 that consume all kinds of energy resources, collection units 210, 220 and 230 for collecting information on energy resources consumed by the energy consumption devices 110, 120 and 130, an integrated resource relation map management unit 300 for generating and managing an integrated resource relation map by using the information on energy resources collected from the collection units 210, 220 and 230, and an energy management unit 400 for providing energy-saving measures.

The energy consumption devices 110, 120 and 130 refers to as devices consuming energy resources such as electricity, gas and water in a house or a building and may include, e.g., electric/electronic equipments such as microwave oven, refrigerator and lighting, gas equipments such as gas stove, and water equipments.

The collection units 210, 220 and 230 measures consumptions of energy resources consumed by the energy consumption devices 110, 120 and 130 and collects resource information of the energy consumption devices 110, 120 and 130, e.g., collects model names, a power consumption amount of each model and the like thereof.

The energy consumptions of the energy consumption devices 110, 120 and 130 and the resource information thereof collected by the collection units 210, 220 and 230 are delivered to the integrated resource relation map management unit 300.

The integrated resource relation map management unit 300 generates the integrated resource relation map, which indicates correlations between energy resources one another consumed by the energy consumption devices 110, 120 and 130, by using the energy consumptions and resource information of the energy consumption devices 110, 120 and 130.

The energy management unit 400 receives the integrated resource relation map to generate the energy-saving measures such as a usage manner of each of the energy consumption devices 110, 120 and 130 for saving entire energy consumption. These energy-saving measures are provided directly or indirectly to a user so as to help the user effectively save energy.

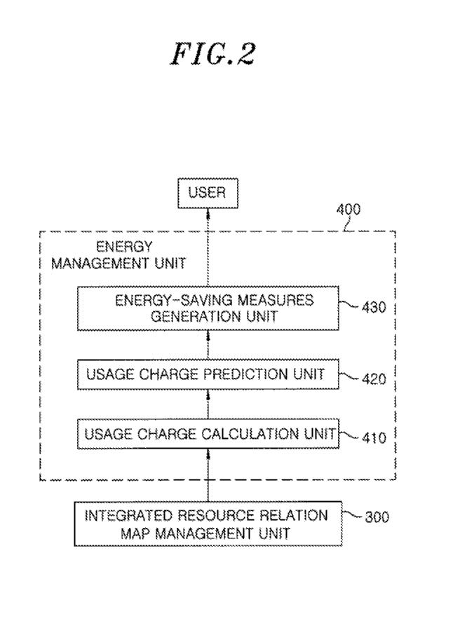

FIG. 2 depicts a detailed block diagram of an energy management unit shown in FIG. 1.

Referring FIG. 2, the energy management unit 400 includes a usage charge calculation unit 410, a usage charge prediction unit 420 and an energy-saving measures generation unit 430.

The usage charge calculation unit 410 receives, from the collection units 210, 220 and 230, the energy consumptions consumed by the energy consumption devices 110, 120 and 130 to calculate a usage charge of energy according to actual energy usage by using reference conversion information of each energy resource based on the energy consumptions.

The usage charge prediction unit 420 predicts, based on the actual energy usage and the usage charge provided from the usage charge calculation unit 410, energy usage by a different period, i.e., on a daily, weekly, monthly and/or yearly basis, in the future and further predicts usage charge according to the predicted energy usage. Herein, the prediction may be performed in consideration of various parameters such as energy usage pattern, history and the like, in order to provide more accurate prediction.

The energy-saving measures generation unit 430 produces energy consumption information of each of the energy consumption devices 110, 120 and 130 based on the usage charge of energy according to the actual energy usage and the predicted usage charge of energy according to the predicted energy usage in the future. The energy-saving measures generation unit 430 generates the energy-saving measures which propose a user to reduce a specific energy resource such as electricity, water or gas when it is determined that the specific energy resource is much used based on the energy consumption information.

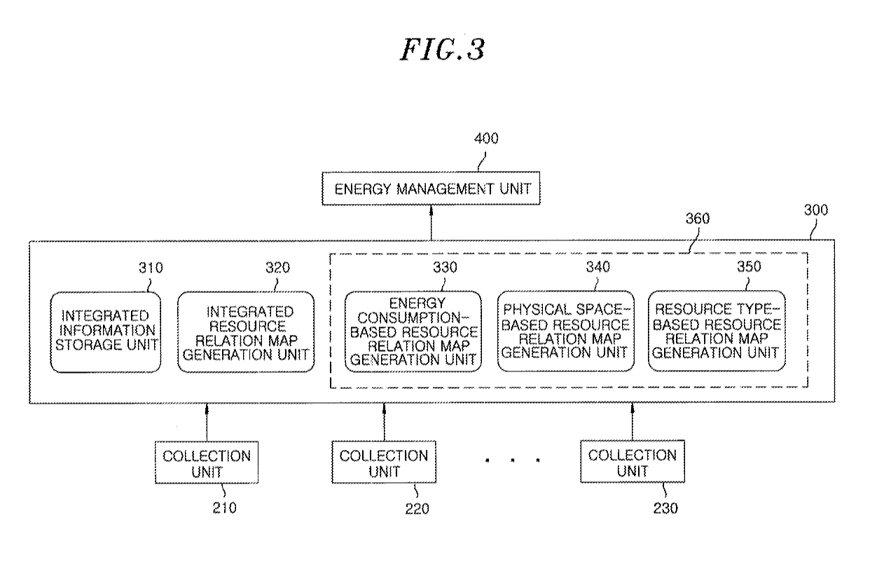

FIG. 3 illustrates a detailed block diagram of an integrated resource relation map management unit shown in FIG. 1.

Referring to FIG. 3, the integrated resource relation map management unit 300 includes an integrated information storage unit 310, an integrated resource relation map generation unit 320 and a resource relation map generation unit 360.

The integrated information storage unit 310 stores, on a resource basis, the resource information on the energy consumption devices 110, 120 and 130 and the energy consumptions consumed by the energy consumption devices 110, 120 and 130, which are provided from the collection units 210, 220 and 230.

The integrated resource relation map generation unit 320 generates the integrated resource relation map which indicates correlations between the resources one another, by using the stored resource information and energy consumptions of the energy consumption devices 110, 120 and 130.

The resource relation map generation unit 360 classifies the resources depending on a variety of criteria to generate a resource relation map by each classification, based on the stored resource information and energy consumptions of the energy consumption devices 110, 120 and 130. Specifically, the resource relation map generation unit 360 contains an energy consumption-based resource relation map generation unit 330, a physical space-based resource relation map generation unit 340 and a resource type-based resource relation map generation unit 350.

The energy consumption-based resource relation map generation unit 330 classifies the resources by energy consumptions thereof to generate a resource relation map indicating correlations between the resources according to the energy consumptions. The physical space-based resource relation map generation unit 340 classifies the resources by physical spaces (areas) thereof to generate a resource relation map indicating correlations between the resources according to the physical spaces. The resource type-based resource relation map generation unit 350 classifies the resources by resource types thereof to generate a resource relation map indicating correlations between the resources according to the resource types.

Apart from that, the classification may be performed depending on a variety of criteria such as functions, kinds, characteristics and the like of the resources.

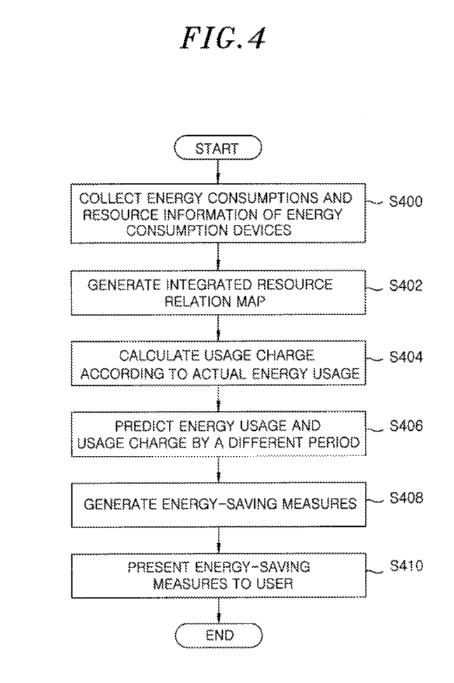

FIG. 4 is a flowchart showing an operation of the apparatus for managing energy resources based on the integrated resource relation map in accordance with the embodiment of the present invention. Hereinafter, the embodiment will be described in detail with reference to FIGS. 1 to 4.

The collection units 210, 220 and 230 measures consumptions of energy resources such as electricity, gas, water and the like consumed by the energy consumption devices 110, 120 and 130 and collects resource information, e.g., model names, power consumption amounts and the like of the energy consumption devices 110, 120 and 130 in step S400. The measured energy consumptions and the collected resource information of the energy consumption devices 110, 120 and 130 are transferred to the integrated resource relation map management unit 300.

Then, in step S402, the integrated resource relation map management unit 300 generates, based on the energy consumptions and the resource information of the energy consumption devices 110, 120 and 130, an integrated resource relation map which indicates correlations between the energy resources one another consumed by the energy consumption devices 110, 120 and 130. The integrated resource relation map is provided to the energy management unit 400, along with the energy consumptions and resource information of the energy consumption devices 110, 120 and 130.

Next, in step S404, the usage charge calculation unit 410 of the energy management unit 400 calculates a usage charge of energy according to actual energy usage by using reference conversion information of each energy resource based on the energy consumptions of the energy consumption devices 110, 120 and 130.

The usage charge prediction unit 420 predicts, based on the actual energy usage and usage charge provided from the usage charge calculation unit 410, energy usage by a different period, i.e., on a daily, weekly, monthly and/or yearly basis, in the future and further predicts a usage charge according to the predicted energy usage in step S406.

Thereafter, in step S408, the energy-saving measures generation unit 430 generates energy-saving measures that propose, e.g., a usage manner of each of the energy consumption devices 110, 120 and 130 for saving entire energy consumption, by using the integrated resource relation map generated by the integrated resource relation map management unit 300, the actual energy usage and usage charge obtained by the usage charge calculation unit 410, and the predicted future energy usage and usage charge obtained by usage charge prediction unit 420.

The energy-saving measures, as well as the actual energy usage along with its corresponding usage charge and the predicted future energy usage along with its corresponding usage charge, are directly or indirectly presented to a user in step S410, so that the user can select the presented energy-saving measures to effectively save energy.

Meanwhile, in step S402, the integrated resource relation map management unit 300 may generate, in addition to the integrated resource relation map, various resource relation maps according to, e.g., energy consumptions, areas, kinds and characteristics of the resources and deliver the same to the energy management unit 400.

Then, the energy management unit 400 generates energy-saving measures on a group basis based on the various resource relation maps, the group including areas, kinds, characteristics and the like of the resources. For example, the energy management unit 400 may generate energy-saving measures which recommend to limit or reduce the use of energy consumption devices within a specific area when it is determined that the specific area consumes much more energy than other areas in reference to a resource relation map according to areas.

As described above, the present invention collects energy information used in a house or a building to construct an integrated resource relation map, and calculates actual energy usage and its corresponding usage charge and future energy usage and its corresponding usage charge on a period basis to show the same to a user. Furthermore, the present invention generates energy-saving measures based on the resource relation map and the calculated energy usages and usage charges, and provides the energy-saving measures to the user. Thus, the present invention allows the user to acknowledge the future energy usage and usage charge on a period basis as well as the present energy usage and usage charge and attracts the user to save energy by employing the energy-saving measures provided.

While the invention has been shown and described with respect to the embodiments, it will be understood by those skilled in the art that various changes and modification may be made without departing from the scope of the invention as defined in the following claims.

What is claimed is:

1. An apparatus for managing energy resources, comprising:
a collection unit for collecting energy consumptions and resource information of a plurality of energy consumption devices;
an integrated resource relation map management unit for generating and managing an integrated resource relation map which indicates correlations between energy resources one another consumed by the energy consumption devices by using the energy consumptions and the resource information; and
an energy management unit for generating energy-saving measures based on the integrated resource relation map.

2. The apparatus of claim 1, wherein the integrated resource relation map management unit includes:
an integrated information storage unit for storing, on a resource basis, the resource information and the energy consumptions of the energy consumption devices;
an integrated resource relation map generation unit for generating the integrated resource relation map; and
a resource relation map generation unit for classifying the energy resources by various criteria to generate various resource relation maps according to respective classifications.

3. The apparatus of claim 2, wherein the various resource relation maps contains:
a resource relation map indicating correlations between the energy resources according to energy consumptions thereof;
a resource relation map indicating correlations between the energy resources according to locational areas thereof; and
a resource relation map indicating correlations between the energy resources according to resource types thereof.

4. The apparatus of claim 2, wherein the energy management unit generates the energy-saving measures on a group basis, based on the various resource relation maps generated by the resource relation map generation unit, the group including areas, kinds and characteristics.

5. The apparatus of claim 1, wherein the energy management unit includes:
a usage charge calculation unit for calculating a usage charge according to actual energy usage of the energy consumption devices;
a usage charge prediction unit for predicting, based on the actual energy usage and the usage charge, future energy usage by a predetermined period, and calculating future usage charge according to the predicted future energy usage; and
an energy-saving measures generation unit for generating the energy-saving measures based on the predicted future energy usage and the calculated future usage charge.

6. The apparatus of claim 1, wherein the energy consumption devices refer to as devices consuming energy resources in a house or in a building.

7. The apparatus of claim 1, wherein the energy resources include at least one of electricity, gas and water.

8. A method for managing energy resources, comprising:
collecting energy consumptions and resource information of a plurality of energy consumption devices;
generating an integrated resource relation map which indicates correlations between energy resources one another consumed by the energy consumption devices by using the energy consumptions and the resource information; and
generating energy-saving measures based on the integrated resource relation map.

9. The method of claim 8, wherein said generating the integrated resource relation map includes:
storing, on a resource basis, the resource information and the energy consumptions of the energy consumption devices;
generating the integrated resource relation map;
classifying the energy resources by various criteria; and
generating various resource relation maps according to respective classifications.

10. The method of claim 9, wherein the energy-saving measures is generated on a group basis, based on the various resource relation maps, the group including areas, kinds and characteristics of the resources.

11. The method of claim 9, wherein the various resource relation maps contains:
a resource relation map indicating correlations between the energy resources according to energy consumptions thereof;
a resource relation map indicating correlations between the energy resources according to locational areas thereof; and
a resource relation map indicating correlations between the energy resources according to resource types thereof.

12. The method of claim 8, wherein said generating the energy-saving measures includes:
calculating a usage charge according to actual energy usage of the energy consumption devices;
predicting, based on the actual energy usage and the usage charge, future energy usage by a predetermined period;
calculating future usage charge according to the predicted future energy usage; and
generating the energy-saving measures based on the predicted future energy usage and the calculated future usage charge.

13. The apparatus of claim 8, wherein the energy consumption devices refer to as devices consuming energy resources in a house or in a building.

14. The apparatus of claim 8, wherein the energy resources include at least one of electricity, gas and water.
